(19) United States
(12) Patent Application Publication
(10) Pub. No.: US 2006/0012298 A1
(43) Pub. Date: Jan. 19, 2006

(54) LED chip capping construction

(75) Inventors: Ming-Shun Lee, Taipei (TW); Ping-Ru Sung, Taipei (TW)

Correspondence Address: TROXELL LAW OFFICE PLLC, SUITE 1404, 5205 LEESBURG PIKE, FALLS CHURCH, VA, 22041, US

(73) Assignee: Taiwan Oasis Technology Co., Ltd.

(21) Appl. No.: 10/890,100

(22) Filed: Jul. 14, 2004

(51) Int. Cl. H01L 33/00

(52) U.S. Cl. 313/512; 257/98; 257/100

(57) ABSTRACT

A chip capping construction for a light emitting diode having capped a transparent transitional layer on the top of the chip; a convex functional layer mixed with fluorescent material being capped on the top of the transparent transitional layer; the thickness at where the functional layer in relation to the top layer of the chip being greater than that of the functional layer in relation to the peripheral of the chip; and the greater thickness balancing the wavelength incorporation of the fluorescent material respectively with the top layer and the peripheral layer of the chip to effectively inhibit the creation of diaphragm of strange color.

### BACKGROUND OF THE INVENTION

(a) Field of the Invention

The present invention is related to an LED chip capping technology, and more particularly, to one that effectively eliminate diaphragm of strange color.

(b) Description of the Prior Art

As illustrated in FIG. 1 of the accompanying drawings for a schematic view of a construction of a light emitting diode (LED) providing specific light color effects by having the light emission from the chip incorporated with wave length of fluorescent material, the LED relates to a packaging containing conductors 10 of different polarities and a carrier 20. The carrier 20 is fixed with a chip 30 and a fluorescent material 40 while an electrode layer 31 of the chip 30 and the conductors 10 are connected by means of a golden plated wire 50.

Once the conductors 10 are conducted, light emitted from the chip 30 passing through the fluorescent material 40 is incorporated with the wavelength of the fluorescent material 40 to create a specific light color. For example, the white light LED of the prior art has its chip to emit blue light through yellow fluorescent material to provide white light effects. Whereas the LED of the prior art as illustrated in FIG. 1, the space above the chip 30 is not capped by the fluorescent material; the light emitted straight up from the chip 30 is not subject to the incorporation of wavelength with the fluorescent material as those lights reflected from the peripheral of the chip 30 and is vulnerable to create significant diaphragm of strange color.

An improvement is made by having capping the surface of the chip 30 a comparatively thick while insulation glue in the hope to mitigate the diaphragm of strange color by taking advantage of the light transmission of the white insulation glue. However, the phenomenon of diaphragm of strange color still presents though at a lesser degree. Furthermore, the capping on the chip with the white insulation glue also reduces the luminance of the LED.

### SUMMARY OF THE INVENTION

The primary purpose of the present invention is to provide a chip capping construction for a light emitting diode that effectively inhibit the creation of diaphragm of strange color. To achieve the purpose, additional to the basic construction of having fixed a chip and a fluorescent material to the carrier of the LED and a golden plated wire to connect the electrode layer of the chip and the conductors, a transparent transition layer is capped on the top of the chip, and a functional layer mixed with fluorescent material is further capped on the transition layer. The thickness of the functional layer at where in relation to the top layer of the chip is greater than that in relation to the peripheral of the chip so that the convex functional layer balances the incorporation of wavelength of the lights on the top layer of the chip and on the peripheral of the chip respectively with that of the fluorescent material. Of course, another convex light penetration layer may further cap on the functional layer to provide proper protection for the functional layer, the transitional layer and the chip.

### BRIEF DESCRIPTION OF THE DRAWINGS

FIG. 1 is a schematic view of a construction of a light emitting diode of the prior art.

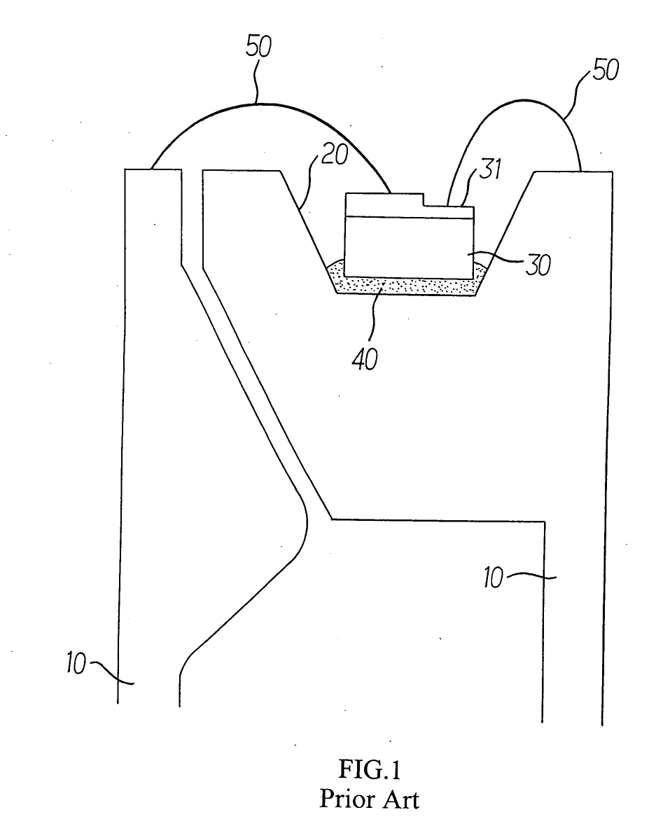

FIG. 2 is a schematic view of a construction of a light emitting diode of a first preferred embodiment of the present invention.

FIG. 3 is a schematic view showing a magnified construction of the capping layer of the LED of the present invention.

FIG. 4 is a schematic view of a construction of a light emitting diode of a second preferred embodiment of the present invention.

### DETAILED DESCRIPTION OF THE PREFERRED EMBODIMENTS

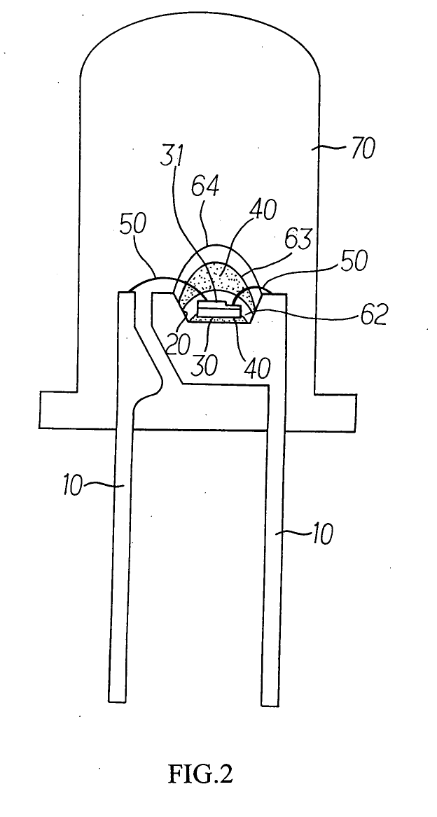

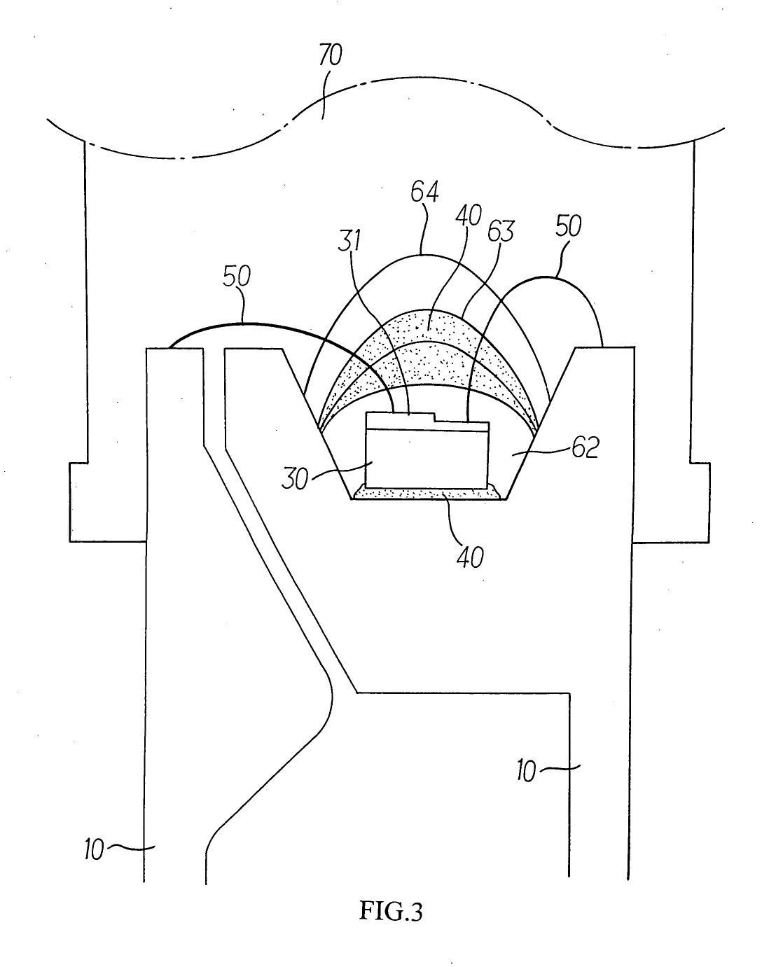

Referring to FIG. 2 for a basic construction of a light emitting diode of the present invention, a packaging 70 contains multiple conductors 10 of different polarities and a carrier 20. The packaging 70 is made of epoxy or a transparent material. A chip 30 and a fluorescent material 40 are placed in the carrier. A golden plated wire 50 connects an electrode layer 31 of the chip 30 and those conductors 10. Accordingly, once those conductors 10 are conducted, the light emitted form the chip 30 passing through the fluorescent material is incorporated with the wavelength of the fluorescent material 40 to form a specific light color. Also as illustrated in FIG. 3, the top of the chip 30 is capped with a transparent transitional layer 62. The top of the transparent transition layer 62 is capped with a functional layer 63 mixed with fluorescent material 40. In the preferred embodiment, the transparent transition layer 62 is related to a convex structure of hardened transparent insulation glue; and the functional layer 63 is related to an admixture of powders of fluorescent material 40 and epoxy also hardened into a convex structure. The top of the functional 63 may be further capped with another hardened, convex layer 64 pervious to light of the same transparent insulation glue to protect the chip and avoid creating the phenomenon of diaphragm of strange color.

The present invention is essentially characterized by that the thickness of the capping layer at where the functional layer 63 is in relation to the top layer of the chip 30 is greater than that of the functional layer 63 in relation to the peripheral of the chip 30. Accordingly, the convex functional layer 63 balances the wavelength incorporation of the fluorescent material 40 respectively with the top and the peripheral of the chip 30 to effectively inhibit the creation of the diaphragm of strange color.

In the preferred embodiment as illustrated in FIGS. 2 and 3, the carrier is disposed at the bowl structure on the conductors 10 and the bottom of the chip 30 is separately provided with the fluorescent material 40. The fluorescent material 40 provided at the bottom of the chip 30 is related to an admixture of fluorescent powders and the adhesive agent used to fix the chip 30. Therefore, the fluorescent material 40 can be coated at the base layer of the carrier 20 with the bottom of the chip 30 buried into the fluorescent material for a certain section to fix both of the chip 30 and the carrier 20 in place.

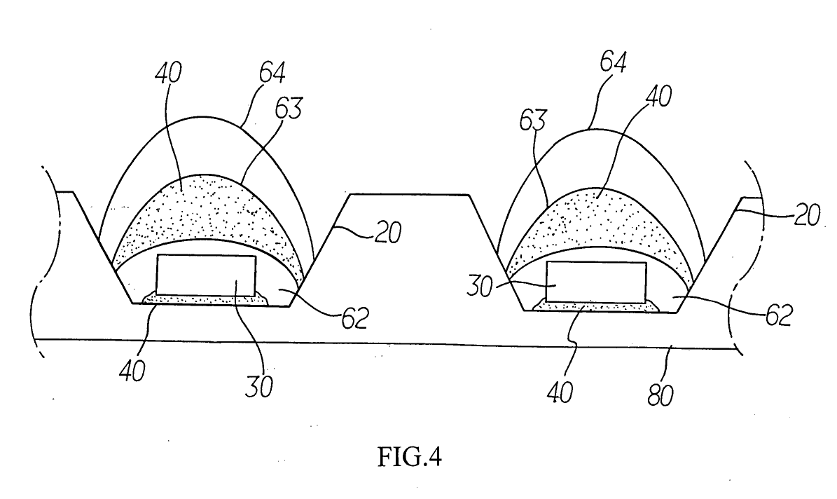

Now referring to FIG. 4 for a second preferred embodiment of the present invention, the LED is directly constructed on a circuit plate 80. The carrier 20 preset with a recess is provided on the circuit board 80. Each conductor (not illustrated) is directly laid on the circuit contact of the circuit board 80. The fluorescent material 40, the chip 20, the transitional layer, the functional layer and the light permeable layer are constructed in sequence in the recessed carrier 20 to become the LED on the circuit board 80.

The present invention for providing an improved capping structure for the chip in an LED, this application for a utility patent is duly filed accordingly. However, it is to be noted that that those preferred embodiments disclosed in the specification and the accompanying drawings are in no way limiting the present invention. Therefore, any construction, installation, or characteristics that is same or similar to that of the present invention should fall within the scope of the purposes and claims of the present invention.

I claim:

1. A chip capping construction for a light emitting diode to effectively inhibit the creation of diaphragm of strange color, including a chip and a fluorescent material being fixed to carrier; a golden plated wire connecting an electrode layer of the chip and multiple conductors; a transparent transitional layer being capped on the top of the chip at the carrier; a convex functional layer mixed with fluorescent material being capped on the top of the transparent transitional layer; the thickness at where the functional layer in relation to the top layer of the chip being greater than that of the functional layer in relation to the peripheral of the chip; and the greater thickness balancing the wavelength incorporation of the fluorescent material respectively with the top layer and the peripheral layer of the chip.

2. The chip capping construction for a light emitting diode of claim 1, wherein, a convex light permeable layer is capped on the top of the function layer.

3. The chip capping construction for a light emitting diode of claim 1, wherein, a fluorescent material is provided at the bottom of the carrier with the bottom of the chip buried into the fluorescent material for a given section.

4. The chip capping construction for a light emitting diode of claim 1, wherein, a fluorescent material is provided at the bottom of the carrier with the bottom of the chip buried into the fluorescent material for a given section and the top layer of the functional layer is capped with a transparent light permeable layer.

5. The chip capping construction for a light emitting diode of claim 1, wherein, the functional layer relates to an admixture of epoxy and fluorescent power, hardened into a convex structure.

6. The chip capping construction for a light emitting diode of claim 1, wherein, the transparent transitional layer is made of transparent insulation glue hardened into a convex structure.

7. The chip capping construction for a light emitting diode of claim 3, wherein, both of the transparent transitional layer and the light permeable layer are each made of transparent insulation glue hardened into a convex structure.
